(19) United States
(12) Patent Application Publication
(10) Pub. No.: US 2024/0001489 A1
(43) Pub. Date: Jan. 4, 2024

(54) HIGH-EFFICIENCY AND HIGH-PRECISION COMBINED MACHINING EQUIPMENT AND METHOD FOR DIAMOND WAFER SHEET

(71) Applicant: ZHENGZHOU RESEARCH INSTITUTE FOR ABRASIVES & GRINDING CO., LTD., Henan (CN)

(72) Inventors: Jianhui Zhu, Henan (CN); Chaoyu Shi, Henan (CN); Yanjun Zhao, Henan (CN); Yuchun Xu, Henan (CN); Ningchang Wang, Henan (CN); Xuanyang Guo, Henan (CN); Junyong Shao, Henan (CN)

(21) Appl. No.: 17/976,385

(22) Filed: Oct. 28, 2022

(30) Foreign Application Priority Data
Jun. 29, 2022 (CN) 202210759807.8

(51) Int. Cl. B23K 26/40; B23K 26/08; B23K 26/70

(52) U.S. Cl. CPC B23K 26/40; B23K 26/0861; B23K 26/70; B23K 2103/50

(57) ABSTRACT

A high-efficiency and high-precision combined machining apparatus for a diamond wafer sheet and a combined high-efficiency and high-precision method for machining a diamond wafer sheet are disclosed. The apparatus can comprise a machining motion platform component installed on a base, a laser machining component, a grinding component, a polishing component and a detection component installed on a support frame. In operation, a high-energy laser beam of the laser machining component can focus on the surface of the diamond wafer sheet to be machined and perform a straight reciprocating irradiation on the diamond wafer sheet, thereby realizing the planarization machining of the diamond wafer sheet. Further, the grinding component and the polishing component realize further high-precision grinding planarization and finishing polishing machining under the action of the laser machining component.

### CROSS-REFERENCE TO RELATED APPLICATION

The present application for patent claims priority to Chinese patent application filing number 2022107598078, and filed on Jun. 29, 2022 with the China National Intellectual Property Administration, the contents of which are hereby incorporated herein by reference in its entirety and for all purposes.

### TECHNICAL FIELD

The present disclosure relates to the technical field of diamond machining, in particular to a high-efficiency and high-precision combined machining equipment and a high-efficiency and high-precision combined machining method for a diamond wafer sheet.

### BACKGROUND ART

At present, diamond is an advanced functional material that integrates many excellent properties such as strength, heat, light, electricity, and sound. Diamond is also a key basic material utilized in many industries such as semiconductor, optical window, and sewage treatment, and has broad application prospects.

Chinese patent application number CN201811415381.4 discloses a method for laser-assisted polishing of CVD diamond, which utilizes two separate processes of laser rough polishing and mechanical fine polishing to achieve CVD diamond surface polishing. This method of laser-assisted polishing solves a problem that laser polishing is prone to: namely the production of a graphitized layer. It also overcomes the lower efficiency of mechanical polishing. Further, Chinese patent application number CN201910847236.1 discloses a laser in-situ assisted grinding method for a typical crystal plane of a single-crystal diamond, which uses the laser beam to inject in a hard-to-grind direction of an illuminating surface of the single-crystal diamond to soften the hardness of the single-crystal diamond grinding surface in the hard-to-grind direction. This improves the grinding efficiency of the grinding disc for single-crystal diamond, but is not applicable to CVD diamond wafer sheet. Achieving high-efficiency and high-precision planarization machining and polishing machining of CVD diamond wafer sheet is a problem still to be solved.

### SUMMARY

The purpose of the present disclosure is to provide a high-efficiency and high-precision combined machining apparatus and a high-efficiency and high-precision combined machining method for a diamond wafer sheet. Embodiments of the present disclosure can integrate two or even three processes of laser machining, grinding and polishing, and can achieve combined machining, having complementary advantages and breaking through size limitation of CVD diamond wafer sheet. Moreover, the high-efficiency and high-precision planarization machining and polishing machining are carried out for different sizes and types of CVD diamond wafer sheets, so that the after-processing curvature, warpage, total thickness deviation, surface roughness and other indicators meet the application requirements.

The technical solutions adopted in the present disclosure are as follows.

A high-efficiency and high-precision combined machining equipment for a diamond wafer sheet, comprising a machine frame, wherein the machine frame comprises a base and a support frame, and the support frame is fixedly provided on the base, and a machining motion platform component configured to fix a workpiece to be machined and capable of moving in mutual perpendicular directions of a horizontal plane and rotating in the horizontal plane is installed on the base, a laser machining component, a grinding component, a polishing component and a detection component are installed on the support frame,

wherein the laser machining component comprises a laser emitting apparatus, a YZ-direction biaxial motion sliding table, and a laser rotating shaft, the YZ-direction biaxial motion sliding table is installed on the support frame, and the laser emitting apparatus is fixed on the YZ-direction biaxial motion sliding table through the laser rotating shaft, through a movement of the YZ-direction biaxial motion sliding table and the laser rotating shaft, the high-energy laser beam can be focused on a surface of the diamond wafer sheet to be machined, and an incident angle of a high-energy laser beam and a horizontal Y-direction straight reciprocating irradiation of a laser spot are adjusted;

the grinding component comprises a first swing frame, a first pressing cylinder, a grinding motorized spindle, a grinding disc, a grinding liquid filtering and circulating apparatus and a flexible scraper blade; wherein one end of the first swing frame is installed on the support frame and can make arc swing around its own rotating shaft in the horizontal plane; the first pressing cylinder is fixed on the first swing frame, the first pressing cylinder is provided vertically downward, a movable end of the first pressing cylinder is connected to the grinding motorized spindle, and a rotating shaft of the grinding motorized spindle is connected to the horizontally provided grinding disc, and the grinding disc is driven by the first swing frame to move to a grinding station above the machining motion platform component; and the flexible scraper blade is fixed on a shell of the grinding motorized spindle, and is close tightly to an outside of the grinding disc;

the polishing component comprises the second swing frame, the second pressing cylinder, a polishing motorized spindle, and a disc-shaped diamond grinding wheel, wherein one end of the second swing frame is installed on the support frame, and can make arc swing around its own rotating shaft in the horizontal plane; the second pressing cylinder is fixed on the second swing frame, the second pressing cylinder is provided vertically downward, the movable end of the second pressing cylinder is connected to the polishing motorized spindle, and the rotating shaft of the polishing motorized spindle is connected to the horizontally provided disc-shaped diamond grinding wheel, the diamond grinding wheel is driven by the second swing frame to move to a polishing station above the machining motion platform component;

the detection component is provided directly above the machining motion platform component, which comprises a Z-direction vertical displacement sliding table and a line laser displacement sensor, wherein the line laser displacement sensor is fixed vertically downward on the Z-direction vertical displacement sliding table, and configured to scan a surface of the diamond to be machined, so as to obtain a morphology height displacement data;

when the grinding component, polishing component, and detection component are all located at the machining station, the grinding disc, the line laser displacement sensor, and the disc-shaped diamond grinding wheel are in sequence arranged in a straight line from the grinding station to the polishing station, and the straight line is parallel to a X direction and perpendicularly intersects with a rotation axis of the diamond wafer sheet; the flexible scraper blade is provided between the grinding station and the polishing station; and an irradiation area of the laser machining component is located between the grinding station and polishing station; and

an output end of the line laser displacement sensor is connected to an input end of the central controller, and the output end of the central controller is respectively connected to control input ends of the laser emitting apparatus, the machining motion platform component, the laser machining component, the grinding component, the polishing component, and the detection component.

The machining motion platform component comprises an XY-direction two-dimensional horizontal motion platform in a horizontal plane, a rotating carrier platform, and a transition carrier plate and a vacuum adsorption apparatus, wherein the XY-direction two-dimensional horizontal motion platform, the rotating carrier platform, and the transition carrier plate are in sequence provided from bottom to top, and a upper end surface of the rotating carrier platform is provided with gas holes and gas passages, and the gas holes and gas passages are connected to a suction port of the vacuum adsorption apparatus through a rotating joint; the transition carrier plate and the rotating carrier platform are provided coaxially; a central position of a upper end surface of the transition carrier plate is provided with a circular groove configured to make the workpiece to be machined placed, and several through holes are evenly distributed in the circular groove, the through holes communicate with the gas passages on a upper surface of the rotating carrier platform; a diameter of the circular groove of the transition carrier plate is the same as a diameter of the diamond wafer sheet to be machined, and a depth of the circular groove is smaller than a thickness of the diamond wafer sheet to be machined.

An edge position of a lower disk surface of the grinding disc is provided with a circular ring protrusion, and a grid-shaped diversion trench is provided on the circular ring protrusion, and several diversion holes are evenly distributed in the diversion trench, a liquid flow channel is provided inside the grinding disc, and the liquid flow channel is communicated with all the diversion holes, the other end of the liquid flow channel is led to a total liquid inlet in the center of the grinding disc and communicated with a liquid outlet of the grinding liquid filtering and circulating apparatus through the rotating joint and a hose;

the equipment further comprises a metal housing, and the metal housing is covered on the base for wrapping and protection.

The present disclosure provides a high-efficiency and high-precision combined machining method for a diamond wafer sheet, which comprises following steps of:

placing a diamond wafer sheet to be machined at a machining station, and obtaining a highest point position information of the diamond wafer sheet and a surface precision result of the surface flatness;

setting a laser incident angle, a laser machining power, a straight reciprocating speed of the laser in a Y-direction, a straight reciprocating speed of the diamond wafer sheet in an X-direction, a rotational speed of a grinding disc and a rotational speed of a diamond grinding wheel, and gas supply pressures of a first pressing cylinder and a second pressing cylinder;

the diamond wafer sheet making a reciprocating motion in the X direction at a set speed, the laser emitting apparatus making a straight reciprocating motion in the Y-direction at the set speed, and the high-energy laser beam making a straight reciprocating irradiation on the diamond wafer sheet in the Y-direction at a set incident angle to perform laser planarization machining;

the grinding disc and the diamond grinding wheel rotating under an action of the laser, at a constant speed according to their respective set rotational speeds, and the first pressing cylinder and the second pressing cylinder pressing downwards for grinding and polishing, so as to achieve further high-precision grinding planarization and finishing polishing machining, simultaneously, turning on, during a machining process, a grinding liquid filtering and circulating apparatus, wherein in the process of machining, the surface precision of the diamond wafer sheet is detected in real time, and a central controller performs data processing in real time to obtain a current machined surface precision of the diamond wafer sheet; and

the diamond wafer sheet self-rotating, after the diamond wafer sheet completes one X-direction straight reciprocating stroke range, by a certain angle, and starting to execute a next X-direction reciprocating machining cycle until the machining requirements are reached before ending.

The method specifically comprises the following steps:

step 1: performing in-situ detection on the surface precision of diamond wafer sheet:
1.1: fixing the diamond wafer sheet: placing the diamond wafer sheet in a central circular groove of a transition carrier plate, and turning on a vacuum adsorption to fix the diamond wafer sheet and the transition carrier plate;
1.2: adjusting a detection position: turning on a line laser displacement sensor to emit a measurement laser beam for irradiating on a surface of the diamond wafer sheet, a Z-direction vertical displacement sliding table driving the line laser displacement sensor to move up or down, and adjusting a height position of the line laser displacement sensor distancing from the diamond wafer sheet, so that the line laser displacement sensor detects a middle value of a displacement value located in a measuring range thereof; then, a XY-direction two-dimensional horizontal motion platform moving to adjust a front-and-rear Y-direction position of the diamond wafer sheet, so that a linear laser beam emitted by the line laser displacement sensor can cover a diameter line of the diamond wafer sheet; finally, the XY-direction two-dimensional horizontal motion platform driving the diamond wafer sheet to move in a left-and-right X direction to one side of the line laser displacement sensor; and
1.3: performing the in-situ detection and data processing: the XY-direction two-dimensional horizontal motion platform driving the diamond wafer sheet to move at a constant speed in the left-and-right X-direction to the other side of the line laser displacement sensor, wherein during the movement, the line laser displacement sensor continuously emits a linear measurement laser beam to scan an entire surface of the diamond wafer sheet, so as to collect a morphology displacement data of the entire surface of the diamond wafer sheet; and obtaining, according to data processing steps such as point cloud coordinate transformation, effective point screening, empty point interpolation, three-dimensional morphology construction, and index value calculation performed in sequence on collected data, the highest point position information of the diamond wafer sheet and the surface precision result of the surface flatness;

step 2: initializing machining conditions:
2.1: adding a protective coating: due to that a upper surface of the diamond wafer sheet is higher than a surface of the transition carrier plate, coating a certain thickness of protective coating along a circumferential side surface of the diamond wafer sheet, so that a thickness of the protective coating is flush with the upper surface of the diamond wafer sheet, wherein after the protective coating is cured, it can not only greatly reduce absorption rate of laser energy on the circumferential side surface of the diamond wafer sheet, but also play a mechanical supporting role on a circumferential edge of the diamond wafer sheet to prevent “edge collapse” problem of diamond wafer sheet occurred in the process of machining;
2.2: adjusting high-energy laser beam focusing: using parameters such as an incident angle of the high-energy laser beam, a laser focal distance, the highest point position coordinate and height of the diamond wafer sheet to calculate coordinate position of a light outlet of the laser emitting apparatus in the front-and-rear Y-direction and an up-and-down Z-direction according to a trigonometric function relationship, and then, enabling, through rotation of laser rotating shaft, movement of the YZ-direction biaxial motion sliding table, and movement of XY-direction two-dimensional horizontal motion platform, the high-energy laser beam emitted by the laser emitting apparatus to be irradiated and focused on the highest point position of the diamond wafer sheet surface at a set incident angle; and
2.3: entering machining station: moving, through rotation of a first swing frame and a second swing frame, the grinding disc and a disc-shaped diamond grinding wheel to above the diamond wafer sheet, respectively, so that the grinding disc, the line laser displacement sensor, and the disc-shaped diamond grinding wheel are in sequence arranged in a straight line from left to right, wherein the straight line is parallel to a X direction and perpendicularly intersects with a rotation axis of the diamond wafer sheet; and the laser emitting apparatus is located directly in front of the line laser displacement sensor;

step 3: setting machining parameters:
3.1: setting laser incident angles: carrying out a proofing test with different laser incident angles on a diamond test piece, recording, under a condition of highest laser power, a difference value of ablation depth between positive focus and 0.02 mm defocus, and selecting a laser incident angle θ when the difference value is the largest as the machining parameter;
3.2: setting laser machining powers: carrying out a proofing test with different laser powers on the diamond test piece, selecting a laser power P₁ with the largest ablation depth and no micro-cracks in an ablation area as a setting power for laser high-efficiency planarization machining, and selecting a laser power P₂ when the ablation depth is 0 and the ablation area is not blackened and darkened as a setting power for a laser low-power thermally induced machining;
3.3: setting reciprocating motion speeds: carrying out a proofing test under a condition of laser P₁ power on the diamond test piece, measuring a shape size (length j, width k) and an area of an ablation pit, and then setting, according to a center repetition frequency Q of a high-power pulsed laser, an ideal spot overlap ratio ϵ, shape size of the ablation pit, and a Y-direction reciprocating motion stroke H, the straight reciprocating speed V_{y} of the laser in a Y-direction and the straight reciprocating speed Vₓ of the diamond wafer sheet in an X-direction, and relational expression is:

V_{y}=j·ϵ·Q

Vₓ=k·ϵ·V_{y}/H
wherein unit of Vₓ is mm/s, unit of V_{y} is mm/s, unit of j is mm, unit of k is mm, unit of Q is Hz, unit of H is mm, and ratio unit of ϵ is 1;
3.4: setting rotational speeds: setting, according to a circular ring protrusion width w₁ of the grinding disc, a working layer width w₂ of the disc-shaped diamond grinding wheel, an ideal repeated grinding coefficient τ₁ of grinding, an ideal repeated grinding coefficient τ₂ of polishing, and the straight reciprocating speed Vₓ of the diamond wafer sheet in an X-direction, the rotational speed n₁ of the grinding disc and the rotational speed n₂ of the disc-shaped diamond grinding wheel; and relational expression is:

n₁=Vₓτ₁·w₁

n₂=Vₓτ₂·w₂
wherein unit of n₁ is r/s, unit of n₂ is r/s, unit of w₁ is mm, unit of w₂ is mm, and ratio unit of τ₁ and τ₂ is 1; and
3.5: setting gas pressures: setting a gas supply pressure R₁ of the first pressing cylinder according to a mass m₁ of a grinding component, an ideal grinding pressure F₁ and a cylinder diameter φ₁ of first pressing cylinder, and setting a gas supply pressure R₂ of the second pressing cylinder according to a mass m₂ of a polishing component, an ideal polishing pressure F₂ and a cylinder diameter φ₂ of the second pressing cylinder; and relational expression is:

R₁=4(F₁−m₁g)/π·φ₁²

R₂=4(F₂−m₂g)/π·φ₂²

wherein unit of R₁ and R₂ is Pa, unit of F₁ and F₂ is N, unit of m₁ and m₂ is kg, unit of φ₁ and φ₂ is m, and g is a constant of gravitational acceleration, and π is a constant of pi; and

step 4: starting combined machining;
4.1: diamond wafer sheet making reciprocating motion in an X-direction; starting the XY-direction two-dimensional horizontal motion platform to drive the diamond wafer sheet to make the straight reciprocating motion in the X-direction according to the set speed Vₓ;
4.2: performing reciprocating laser machining in a Y-direction: starting the YZ-direction biaxial motion sliding table to drive the laser emitting apparatus to make the straight reciprocating motion in the Y-direction according to the set speed V_{y}, so that the high-energy laser beam performs the straight reciprocating irradiation on the diamond wafer sheet in the Y direction at the set incident angle θ, which cooperates with the X-direction reciprocation of the diamond wafer sheet to achieve the laser planarization machining of high point more removal material and low point less removal material on the entire surface of the diamond wafer sheet;
4.3: performing combined grinding and polishing machining under the action of laser: starting a grinding motorized spindle and a polishing motorized spindle, so that the grinding disc and disc-shaped diamond grinding wheel rotate at a constant speed according to their respective set rotational speeds n₁ and n₂, and the circular ring protrusion of the grinding disc and the working layer of the disc-shaped diamond grinding wheel contact the surface of the diamond wafer sheet through pressing actions and pressures of the first pressing cylinder and the second pressing cylinder, so as to achieve further high-precision grinding planarization and finishing polishing machining; and simultaneously, turning on the grinding fluid filtering and circulating apparatus, so that the diamond grinding fluid is injected into a grinding area on the surface of the diamond wafer sheet from a liquid flow channel, diversion holes and diversion trench of the grinding disc, and the flexible scraper blade is close tightly to the surface of the diamond wafer sheet to prevent the grinding fluid from flowing into the laser machining area and polishing area;
4.4: performing real-time detection on surface precision: starting the line laser displacement sensor to collect surface morphology data when the diamond wafer sheet makes a straight reciprocation in the X direction, and performing real-time data processing in the central controller to obtain a current machining surface precision of diamond wafer sheet; and
4.5: performing rotary machining on diamond wafer sheet, wherein a stroke range of the X-direction straight reciprocation of the diamond wafer sheet is that one edge of the diamond wafer sheet is polishing-machined in place by the disc-shaped diamond grinding wheel, and the other edge of the diamond wafer sheet is grinding-machined in place by the grinding disc; after completing one X-direction reciprocation, the diamond wafer sheet self-rotates by a certain angle ω, starting to execute the next X-direction reciprocating machining cycle until end.

When the diamond wafer sheet moves from the polishing station to the grinding station in the X direction, laser machining and grinding machining are mainly used to achieve high-efficient and high-precision planarization machining of the surface of the diamond wafer sheet, comprising that: high-power laser quickly removes materials for improving the surface precision of diamond wafer sheet to achieve high-efficient planarization machining of the surface laser machining area, and then molten chips, impact pits, and graphite layers etc. left in the laser machining area are removed by being grinded to achieve further high-precision planarization machining, and simultaneously, the grinding fluid quickly flows into the area where the laser machining is completed, and takes away heat generated by the laser machining on the diamond wafer sheet, thereby avoiding thermal stress or thermal deformation caused by heat accumulation.

When the diamond wafer sheet moves from the grinding station to the polishing station in the X direction, the laser power is reduced, and polishing machining of the surface of diamond wafer sheet is realized by polishing with the aid of low-power laser thermal induction; specifically, low-power laser irradiating on the surface of diamond wafer sheet is not enough to destroy internal crystal structure of the diamond, but absorbed laser energy heats the surface of the diamond wafer sheet in a form of heat conduction, thereby making a diamond difficult-to-grind material softened, and then the disc-shaped diamond grinding wheel polishes the diamond wafer sheet, removes an extremely thin material layer on the surface, reduces surface roughness of the diamond wafer sheet, thereby quickly completing the polishing machining of the diamond wafer sheet.

During the machining, the laser displacement sensor detects the surface precision result of the diamond wafer sheet in real time, in an early stage of machining, the surface precision of the diamond wafer sheet is poor, so the laser machining continuously uses high power to mainly focus on high-efficiency planarization machining for rapid material removal; in a mid-stage of machining, the surface precision of the diamond wafer sheet reaches a certain requirement, then the laser machining adopts the above-mentioned mode of reciprocating switching between high and low power in the X direction to achieve high-efficiency and high-precision planarization machining, and avoid deterioration of the surface roughness of the diamond wafer sheet; and in a later stage of machining, the surface precision of the diamond wafer sheet has reached a standard, the laser machining continuously uses low power to mainly focus on the polishing machining of extremely thin material removal, and stops machining until when the entire surface roughness of the diamond wafer sheet further reaches the standard.

The method further comprises step 5: performing machining result detection, wherein

when the surface precision result of the diamond wafer sheet detected by the line laser displacement sensor in real time reaches the standard, and the entire surface is polished evenly and has no visible defects, the laser emitting apparatus stops emitting laser light, the line laser displacement sensor stops collecting data, and the first pressing cylinder drives the grinding disc to rise and separate from the diamond wafer sheet, the first swing frame drives the grinding component away from the machining area, the second pressing cylinder drives the disc-shaped diamond grinding wheel to rise and separate from the diamond wafer sheet, the second swing frame drives the polishing component away from the machining area, and then the machining motion platform brings the diamond wafer sheet to a position where it is convenient to take the sheet before stopping the movement; and

a vacuum adsorption apparatus is turned off, the diamond wafer sheet is removed, and a white light interference three-dimensional profiler, a thickness gauge, etc. are used to detect curvature, warpage, surface roughness, total thickness deviation, average thickness and other items of the diamond wafer sheet after machining, so as to verify whether the planarization machining and polishing machining results meet index requirements, if the index requirements are met, the machining ends, and if the index requirements are not met, it returns to corresponding steps for remachining.

In the present disclosure, a machining motion platform component configured to fix a workpiece to be machined and capable of moving in mutual perpendicular directions of a horizontal plane and rotating in the horizontal plane is provided on the base, then, a laser machining component, a grinding component, a polishing component and a detection component are respectively provided at the corresponding positions through the support frame, and then, the above components are controlled by the central processing unit to realize the high-efficiency and high-precision planarization machining and polishing machining of the diamond wafer sheet, which can integrate the three processes of laser machining, grinding and polishing, achieve combined machining and complementary advantages, and solve the problems of high cost of laser high-precision polishing, easy surface damage and low efficiency of mechanical grinding and polishing, improving machining efficiency, reducing defective index, and providing new equipment, new method, and new idea for diamond wafer machining.

### BRIEF DESCRIPTION OF DRAWINGS

In order to explain the embodiments of the present disclosure or the technical solutions in the prior art more clearly, the following briefly introduces the drawings that need to be used in the description of the embodiments or the prior art, obviously, the drawings in the following description are only some embodiments of the present disclosure, for those ordinarily skilled in the art still could obtain other drawings in light of these drawings, without using any inventive efforts.

FIG. 1 is a structural schematic view according to the present disclosure;

FIG. 2 is a right side view of a structure according to the present disclosure;

FIG. 3 is a flow chart according to the present disclosure;

FIG. 4 is a bottom view of a grinding disc according to the present disclosure; and

FIG. 5 is a sectional view of the grinding disc according to the present disclosure.

### DETAILED DESCRIPTION OF EMBODIMENTS

The technical solutions in the embodiments of the present disclosure will be clearly and completely described below in combination with the drawings in the embodiments of the present disclosure, and obviously, the embodiments described are only part of the embodiments of the present disclosure, rather than all embodiments. Based on the embodiments in the present disclosure, all other embodiments obtained by those ordinarily skilled in the art, without making inventive effort, fall within the protection scope of the present disclosure.

As an overview, manufacture of a diamond wafer sheet by a chemical vapor deposition (CVD) process involves several challenges. A CVD produced diamond wafer sheet is often bent with a buckling deformation, resulting in excessive deviation in the total thickness of the wafer. In addition, the surface grains can be coarse and differ in size, resulting in an extremely rough surface, which is often undesirable. To correct the surface roughness, planarization machining and polishing machining must be performed before use. However, CVD diamond has high hardness, stable chemical properties, and is extremely difficult to be machined. At present, the market for CVD diamond functional materials is not yet mature and is still in the market cultivation stage.

The traditional mechanical grinding and polishing process is not only inefficient, but also easy to damage or even break the surface of the CVD diamond wafer sheet. The larger the size of diamond wafer sheet, the greater the machining difficulty and risk of damage and fragmentation. in contrast, a laser machining process of a CVD diamond wafer sheet such as those referenced hereinabove has the advantages of no contact stress, no risk of fragmentation, small area affected by deterioration, and high material removal rate, among others. However, the precision planarization machining and polishing machining of a CVD diamond piece requires very high optical lens performance, laser beam quality, and precision of moving parts of laser machining equipment, and has complex machining technology, resulting in high laser machining cost and low cost performance.

Moreover, the separate processes of laser rough polishing and mechanical fine polishing of the 201811415381.4 application are not disclosed in a manner that can be carried out simultaneously. This reduces the efficiency, and while these processes are suitable for the polishing machining of the diamond surface the machining requirements for diamond surface curvature, surface warping, total thickness deviation and the like can be insufficient. Likewise, while the laser in-situ assisted grinding method for Chinese application number 201910847236.1 improves grinding efficiency, it is applicable to the grinding machining of single-crystal diamond and does not disclose application to high-efficiency and high-precision machining of CVD diamond wafer sheet.

Achieving high-efficiency and high-precision machining of a CVD diamond wafer sheet that overcomes many of these challenges is disclosed herein.

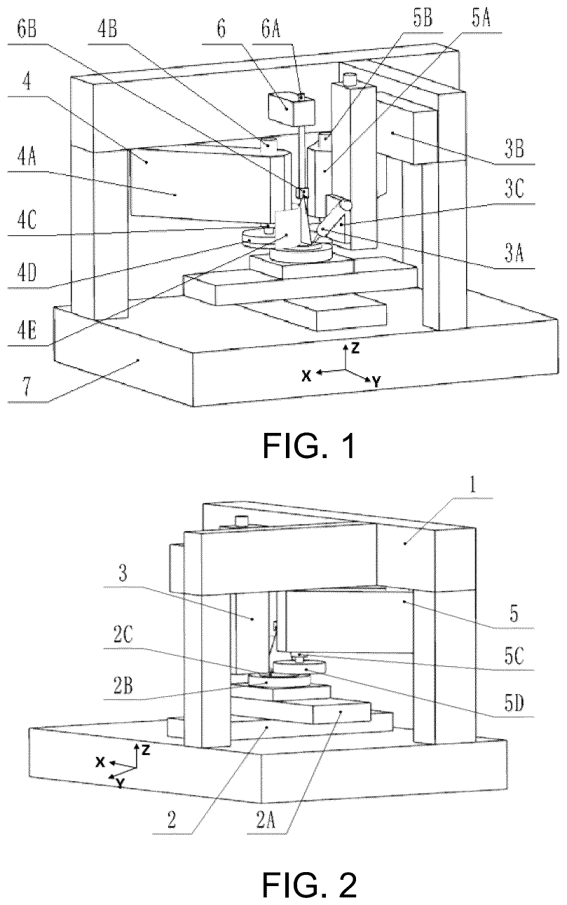

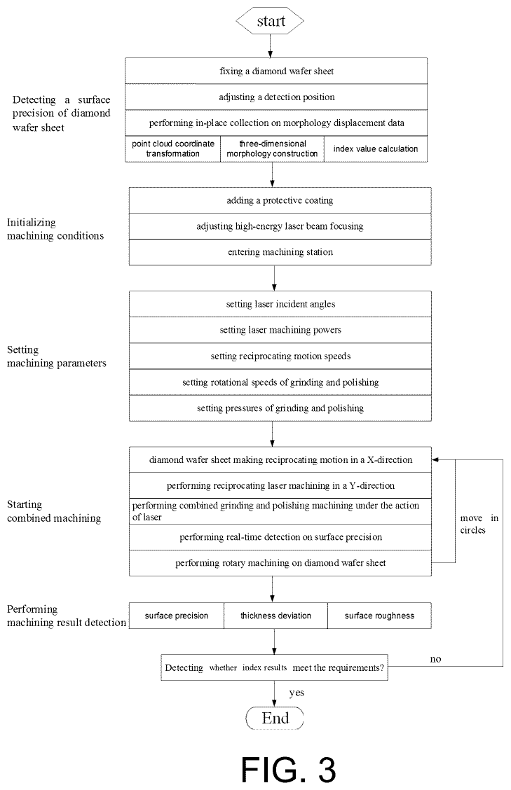

As shown in FIG. 1, FIG. 2 and FIG. 3, the present disclosure includes a laser machining component 3, a grinding component 4, a polishing component 5, a detection component 6, and a machining motion platform component 2 and a central controller configured to fix a workpiece to be machined and capable of moving in mutual perpendicular directions of a horizontal plane and rotating in the horizontal plane.

It also includes a base 7 and a support frame 1, and the support frame 1 is fixedly provided on the base 7. The machining motion platform component 2 is fixed at a central position of the base, and the laser machining component 3, the grinding component 4, the polishing component 5 and the detection component 6 are respectively installed on the support frame 1.

The base 7 and the support frame 1 may be a marble base in actual use that has a certain weight and has both the flatness and roughness of the end surface, and has a small expansion coefficient and does not deform for a long time, which provides a possibility of horizontal arrangement during machining, thereby avoiding the resulting machining errors. The base may also be other materials that meet flatness requirements and are stable.

The machining motion platform component 2 comprises an XY-direction two-dimensional horizontal motion platform 2A in a horizontal plane, a rotating carrier platform 2B, and a transition carrier plate 2C and a vacuum adsorption apparatus, wherein the XY-direction two-dimensional horizontal motion platform 2A, the rotating carrier platform 2B, and the transition carrier plate 2C are in sequence provided from bottom to top, and a upper end surface of the rotating carrier platform 2B is provided with gas holes and gas passages, and the gas holes and gas passages are connected to a suction port of the vacuum adsorption apparatus through a rotating joint; the transition carrier plate 2C and the rotating carrier platform 2B are provided coaxially; a central position of a upper end surface of the transition carrier plate 2C is provided with a circular groove configured to make the workpiece to be machined placed, and several through holes are evenly distributed in the circular groove, the through holes communicate with the gas passages on a upper surface of the rotating carrier platform 2B; a diameter of the circular groove of the transition carrier plate 2C is the same as a diameter of the diamond wafer sheet to be machined, and a depth of the circular groove is smaller than a thickness of the diamond wafer sheet to be machined. The base 7 is placed horizontally after being leveled by feet, and the machining motion platform component 2 is fixed in the center of the plane base platform of the base 7, and the XY-direction two-dimensional horizontal motion platform 2A therein can move in two horizontal directions including the left-and-right X-direction and the front-and-rear Y-direction; the rotating carrier platform 2B is fixed on XY-direction two-dimensional horizontal motion platform 2A, which can rotate at any speed and at any angle at a constant speed; the diamond wafer sheet to be machined is placed in the central circular groove of the transition carrier plate 2C, and the transition carrier plate 2C and the diamond wafer sheet to be machined are fixed on the rotating carrier platform 2B through the vacuum adsorption. The machining motion platform component 2 can drive the diamond wafer sheet to be machined to move and self-rotate on a two-dimensional horizontal plane.

In the above, the laser machining component 3 is provided on the upper and front side of the machining motion platform component 2 as shown in FIG. 1, and includes a laser emitting apparatus 3A, a YZ-direction biaxial motion sliding table 3B, and a laser rotating shaft 30, the laser emitting apparatus 3A is fixed on the YZ-direction biaxial motion sliding table 3B through the laser rotating shaft 30, in actual use, the YZ-direction biaxial motion sliding table 3B of the laser machining component 3 is fixed on the support frame 1, which can move in two directions including a horizontal front-and-rear Y direction and vertical up-and-down Z direction; the laser rotating shaft 3C is fixed on the YZ-direction biaxial motion sliding table 3B, and the laser rotating shaft 3C is connected to the laser emitting apparatus 3A, so that the high-energy laser beam emitted by the laser emitting apparatus 3A can be irradiated on the surface of the diamond wafer sheet to be machined at an incident angle of 0°˜85°. The laser emitting apparatus 3A emits a pulsed laser with long wavelength and large pulse width. In this embodiment, an infrared nanosecond fiber pulse laser is used, through the movements of the YZ-direction biaxial motion sliding table 3B and the laser rotating shaft 3C, the high-energy laser beam can be focused on the surface of the diamond wafer sheet to be machined, so that the incident angle of the high-energy laser beam and the Y-direction straight reciprocating irradiation of the laser spot are adjusted.

The grinding component 4 comprises a first swing frame 4A, a first pressing cylinder 4B, a grinding motorized spindle 4C, a grinding disc 4D, a grinding liquid filtering and circulating apparatus and a flexible scraper blade 4E; wherein one end of the first swing frame 4A is installed on the support frame and can make arc swing around its own rotating shaft in the horizontal plane; the first pressing cylinder 4B is fixed on the first swing frame 4A, the first pressing cylinder 4B is provided vertically downward, a movable end of the first pressing cylinder 4B is connected to the grinding motorized spindle 4C, and a rotating shaft of the grinding motorized spindle 4C is connected to the horizontally provided grinding disc 4D, and the grinding disc is driven by the first swing frame to move to a grinding station above the machining motion platform component; and the flexible scraper blade 4E is fixed on a shell of the grinding motorized spindle 4C, and is close tightly to an outside (right side of the outer edge of the grinding disc is showed in FIG. 1) of the grinding disc 4D.

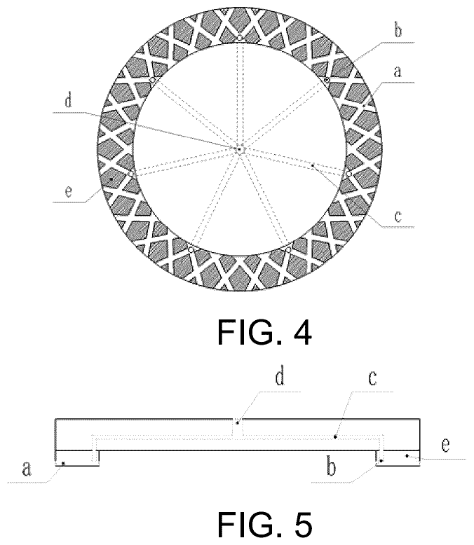

The grinding disc 4D is a cast iron disc in actual use, the structure of the cast iron disc is shown in FIG. 4 and FIG. 5, the surface where the grinding working surface e is located, that is, the edge position of the lower disc surface of the cast iron disc, has a circular ring protrusion, a grid-shaped diversion trench a is provided on the circular ring protrusion, several diversion holes b are evenly distributed in the diversion trench, and a liquid flow channel c is provided inside the grinding cast iron disc, the liquid flow channel c communicates with all the diversion holes b, and the other end of the liquid flow channel c is led to a total liquid inlet d in the center of the cast iron disc and communicated with a liquid outlet of the grinding liquid filtering and circulating apparatus through the rotating joint and a hose. The grinding disc may also be made of other materials that meet machining requirements.

Through the movements of the first swing frame 4A and the first pressing cylinder 4B, the grinding cast iron disc and the flexible scraper blade 4E can be moved onto the diamond wafer sheet to be machined, so that the circular ring protrusion of the grinding cast iron disc and the flexible scraper blade 4E can contact the surface of the diamond wafer sheet to be machined, or the grinding cast iron disc is moved outside the machined area, so that the grinding cast iron disc and the flexible scraper blade 4E are separated from the diamond wafer sheet to be machined.

The polishing component 5 comprises the second swing frame 5A, the second pressing cylinder 5B, a polishing motorized spindle 5C, and a disc-shaped diamond grinding wheel 5D, wherein one end of the second swing frame 5A is installed on the support frame, and can make arc swing around its own rotating shaft in the horizontal plane; the second pressing cylinder 5B is fixed on the second swing frame 5A, the second pressing cylinder 5B is provided vertically downward, the movable end of the second pressing cylinder 5B is connected to the polishing motorized spindle 5C, and the rotating shaft of the polishing motorized spindle 5C is connected to the horizontally provided disc-shaped diamond grinding wheel 5D, the diamond grinding wheel is driven by the second swing frame to move to a polishing station above the machining motion platform component; in actual use, the polishing component 5 is provided on the upper right of the machining motion platform 2. Through the movements of the second swing frame 5A and the second pressing cylinder 5B, the disc-shaped diamond grinding wheel 5D can be moved onto the diamond wafer sheet to be machined, so that the working layer of the disc-shaped diamond grinding wheel 5D contacts the surface of the diamond wafer sheet to be machined, or the disc-shaped diamond grinding wheel 5D is moved outside the machined area, so that the disc-shaped diamond grinding wheel 5D is separated from the diamond wafer sheet to be machined.

The detection component 6 is fixed in the center of the support frame 1 and provided directly above the machining motion platform component 2, which comprises a Z-direction vertical displacement sliding table 6A and a line laser displacement sensor 6B, wherein the line laser displacement sensor 6B emits a linear measurement laser beam to irradiate vertically downward, the line laser displacement sensor 6B is fixed vertically downward on the Z-direction vertical displacement sliding table 6A, and configured to scan the surface of the diamond to be machined, so as to obtain a morphology height displacement data; in actual use, the Z-direction vertical displacement sliding table 6A is fixed on the support frame 1 and can move vertically in the up-and-down Z-direction; the line laser displacement sensor 6B is fixed on the Z-direction vertical displacement sliding table 6A, the line length of linear measurement laser beam is distributed in the front-and-rear Y direction, and is parallel to the Y direction reciprocating irradiation straight line of high-energy laser spot. The upper and lower positions of the line laser displacement sensor 6B can be adjusted through the detection component 6, so that the line laser displacement sensor 6B scans the diamond surface to be machined to obtain the morphology height displacement data.

when the grinding component, polishing component, and detection component are all located at the machining station, the grinding disc, the line laser displacement sensor, and the disc-shaped diamond grinding wheel are in sequence arranged in a straight line from the grinding station to the polishing station, and the straight line is parallel to a X direction and perpendicularly intersects with a rotation axis of the diamond wafer sheet; the flexible scraper blade is provided between the grinding station and the polishing station; and an irradiation machining area of the laser machining component is located between the grinding station and polishing station.

An output end of the line laser displacement sensor 6B is connected to an input end of the central controller, and the output end of the central controller is respectively connected to control input ends of the laser emitting apparatus 3A, the machining motion platform component 2, the laser machining component 3, the grinding component 4, the polishing component 5, and the detection component 6. In actual use, the line laser displacement sensor 6B is connected to the central controller through a signal line, and the collected data of the line laser displacement sensor 6B is transmitted to the central controller for calculation and analysis; simultaneously, the central controller is connected to the laser emitting apparatus 3A through the signal line to transmit control signal for regulating the laser emitting apparatus 3A to emit laser; the central controller is also connected to the motion components such as the machining motion platform component 2, the laser machining component 3, the grinding component 4, the polishing component 5, the motion platform of the detection component 6, the motion sliding table, the rotating shaft, the motorized spindle, and the swing frame through the signal line. Under the control of the central controller, each component operates according to the set process method, and the functions thereof cooperate with each other to automatically complete high-efficiency and high-precision planarization machining and polishing machining of diamond wafer sheet.

It also includes a metal housing, and the metal housing is covered on the marble base and used to wrap and protect the above-mentioned components.

In the present disclosure, a machining motion platform component configured to fix a workpiece to be machined and capable of moving in mutual perpendicular directions of a horizontal plane and rotating in the horizontal plane is provided on the base, then a laser machining component, a grinding component, a polishing component and a detection component are respectively provided at the corresponding positions through the support frame, and then the above-mentioned components are automatically controlled to operate according to the set process method through the central processing unit, so as to realize the high-efficiency and high-precision planarization machining and polishing machining of diamond wafer sheet, and in the process of machining, the setting of detection component 6 can adjust the machining plan and position in real time, thereby better solving the problems of high cost of laser high-precision polishing, easy surface damage and low efficiency of mechanical grinding and polishing, improving machining efficiency, reducing defective index, and providing new equipment, new method, and new idea for diamond wafer machining, and the present disclosure integrates three processes of laser machining, grinding and polishing, achieves combined machining, complementary advantages, and breaks through size limitation of CVD diamond wafer sheet, which not only overcomes the problems of the existing machining methods such as easy damage piece, easy fragmentation, easy deformation, low efficiency and poor precision, but also solves the machining problem of CVD diamond wafer sheet.

The present disclosure also discloses a high-efficiency and high-precision combined machining method for a diamond wafer sheet, the step process thereof is shown in FIG. 3, which specifically includes the following steps:

step 1: performing in-situ detection on the surface precision of diamond wafer sheet:
1.1: fixing the diamond wafer sheet: placing the diamond wafer sheet in a central circular groove of a transition carrier plate 2C, and turning on a vacuum adsorption to fix the diamond wafer sheet and the transition carrier plate 20,
1.2: adjusting a detection position: turning on a line laser displacement sensor 6B to emit a measurement laser beam for irradiating on a surface of the diamond wafer sheet, a Z-direction vertical displacement sliding table 6A driving the line laser displacement sensor 6B to move up or down, and adjusting a height position of the line laser displacement sensor 6B distancing from the diamond wafer sheet, so that the line laser displacement sensor 6B detects a middle value of a displacement value located in a measuring range thereof; then, a XY-direction two-dimensional horizontal motion platform 2A moving to adjust a front-and-rear Y-direction position of the diamond wafer sheet, so that a linear laser beam emitted by the line laser displacement sensor 6B can cover a diameter line of the diamond wafer sheet; finally, the XY-direction two-dimensional horizontal motion platform 2A driving the diamond wafer sheet to move in a left-and-right X direction to one side of the line laser displacement sensor 6B; and
1.3: performing the in-situ detection and data processing: the XY-direction two-dimensional horizontal motion platform 2A driving the diamond wafer sheet to move at a constant speed in the left-and-right X-direction to the other side of the line laser displacement sensor 6B, wherein during the movement, the line laser displacement sensor 6B continuously emits a linear measurement laser beam to scan an entire surface of the diamond wafer sheet, so as to collect a morphology displacement data of the entire surface of the diamond wafer sheet; and obtaining, according to data processing steps such as point cloud coordinate transformation, effective point screening, empty point interpolation, three-dimensional morphology construction, and index value calculation performed in sequence on collected data, the highest point position information of the diamond wafer sheet and the surface precision result of the surface flatness;

step 2: initializing machining conditions:
2.1: adding a protective coating: due to that a upper surface of the diamond wafer sheet is higher than a surface of the transition carrier plate 2C, coating a certain thickness of protective coating along a circumferential side surface of the diamond wafer sheet, so that a thickness of the protective coating is flush with the upper surface of the diamond wafer sheet, wherein after the protective coating is cured, it can not only greatly reduce absorption rate of laser energy on the circumferential side surface of the diamond wafer sheet, but also play a mechanical supporting role on a circumferential edge of the diamond wafer sheet to prevent “edge collapse” problem of diamond wafer sheet occurred in the process of machining;
2.2: adjusting high-energy laser beam focusing: using parameters such as an incident angle of the high-energy laser beam, a laser focal distance, the highest point position coordinate and height of the diamond wafer sheet to calculate coordinate position of a light outlet of the laser emitting apparatus 3A in the front-and-rear Y-direction and an up-and-down Z-direction according to a trigonometric function relationship, and then, enabling, through rotation of laser rotating shaft 3C, movement of the YZ-direction biaxial motion sliding table 3B, and movement of XY-direction two-dimensional horizontal motion platform 2A, the high-energy laser beam emitted by the laser emitting apparatus 3A to be irradiated and focused on the highest point position of the diamond wafer sheet surface at a set incident angle; and
2.3: entering machining station: moving, through rotation of a first swing frame 4A and a second swing frame 5A, the grinding cast iron disc and a disc-shaped diamond grinding wheel 5D to above the diamond wafer sheet, respectively, so that the grinding cast iron disc, the line laser displacement sensor 6B, and the disc-shaped diamond grinding wheel 5D are in sequence arranged in a straight line from left to right, wherein the straight line is parallel to a X direction and perpendicularly intersects with a rotation axis of the diamond wafer sheet; and the laser emitting apparatus 3A is located directly in front of the line laser displacement sensor 6B;

step 3: setting machining parameters:
3.1: setting laser incident angles: carrying out a proofing test with different laser incident angles on a diamond test piece, recording, under a condition of highest laser power, a difference value of ablation depth between positive focus and 0.02 mm defocus, and selecting a laser incident angle 8 when the difference value is the largest as the machining parameter;
3.2: setting laser machining powers: carrying out a proofing test with different laser powers on the diamond test piece, selecting a laser power P₁ with the largest ablation depth and no micro-cracks in an ablation area as a setting power for laser high-efficiency planarization machining, and selecting a laser power P₂ when the ablation depth is 0 and the ablation area is not blackened and darkened as a setting power for a laser low-power thermally induced machining;
3.3: setting reciprocating motion speeds: carrying out a proofing test under a condition of laser P₁ power on the diamond test piece, measuring a shape size (length j, width k) and an area of an ablation pit, and then setting, according to a center repetition frequency Q of a high-power pulsed laser, an ideal spot overlap ratio ϵ, shape size of the ablation pit, and a Y-direction reciprocating motion stroke H, the straight reciprocating speed V_{y} of the laser in a Y-direction and the straight reciprocating speed Vₓ of the diamond wafer sheet in an X-direction, and relational expression is:

_{y}=j·ϵ·Q

R₁=4(F₁−m₁g)/π·φ₁²

Vₓ=k·ϵ·V_{y}/H

wherein unit of Vₓ is mm/s, unit of V_{y} is mm/s, unit of j is mm, unit of k is mm, unit of Q is Hz, unit of H is mm, and ratio unit of ϵ is 1;
3.4: setting rotational speeds: setting, according to a circular ring protrusion width w₁ of the grinding cast iron disc 4D, a working layer width w₂ of the disc-shaped diamond grinding wheel 5D, an ideal repeated grinding coefficient τ₁ of grinding, an ideal repeated grinding coefficient τ₂ of polishing, and the straight reciprocating speed Vₓ of the diamond wafer sheet in an X-direction, the rotational speed n₁ of the grinding cast iron disc 4D and the rotational speed n₂ of the disc-shaped diamond grinding wheel 5D; and relational expression is:

n₁=Vₓ/τ₁·w₁

n₂=Vₓ/τ₂·w₂

wherein unit of n₁ is r/s, unit of n₂ is r/s, unit of w₁ is mm, unit of w₂ is mm, and ratio unit of τ₁ and τ₂ is 1; and
3.5: setting gas pressures: setting a gas supply pressure R₁ of the first pressing cylinder 4B according to a mass m₁ of a grinding component 4, an ideal grinding pressure F₁ and a cylinder diameter φ₁ of first pressing cylinder 4B, and setting a gas supply pressure R₂ of the second pressing cylinder 5B according to a mass m₂ of a polishing component 5, an ideal polishing pressure F₂ and a cylinder diameter φ₂ of the second pressing cylinder 5B, and relational expression is:

R₁=4(F₁−m₁g)/π·φ₁²

R₂=4(F₂−m₂g)/π·φ₂²

wherein unit of R₁ and R₂ is Pa, unit of F₁ and F₂ is N, unit of m₁ and m₂ is kg, unit of φ₁ and φ₂ is m, and g is a constant of gravitational acceleration, and π is a constant of pi; and

step 4: starting combined machining;
4.1: diamond wafer sheet making reciprocating motion in an X-direction: starting the XY-direction two-dimensional horizontal motion platform 2A to drive the diamond wafer sheet to make the straight reciprocating motion in the X-direction according to the set speed Vₓ;
4.2: performing reciprocating laser machining in a Y-direction: starting the YZ-direction biaxial motion sliding table 3B to drive the laser emitting apparatus 3A to make the straight reciprocating motion in the Y-direction according to the set speed V_{y}, so that the high-energy laser beam performs the straight reciprocating irradiation on the diamond wafer sheet in the Y direction at the set incident angle θ, which cooperates with the X-direction reciprocation of the diamond wafer sheet to achieve the laser planarization machining with more material removed at high point and less material removed at low point on the entire surface of the diamond wafer sheet;
4.3: performing combined grinding and polishing machining under the action of laser: starting a grinding motorized spindle 4C and a polishing motorized spindle 5C, so that the grinding cast iron disc and disc-shaped diamond grinding wheel 5D rotate at a constant speed according to their respective set rotational speeds n₁ and n₂, and the circular ring protrusion of the grinding cast iron disc and the working layer of the disc-shaped diamond grinding wheel 5D contact the surface of the diamond wafer sheet through pressing actions and pressures of the first pressing cylinder 4B and the second pressing cylinder 5B, so as to achieve further high-precision grinding planarization and finishing polishing machining; and simultaneously, turning on the grinding fluid filtering and circulating apparatus, so that the diamond grinding fluid is injected into a grinding area on the surface of the diamond wafer sheet from a liquid flow channel, diversion holes and diversion trench of the grinding cast iron disc, and the flexible scraper blade 4E is close tightly to the surface of the diamond wafer sheet to prevent the grinding fluid from flowing into the laser machining area and polishing area, wherein

when the diamond wafer sheet moves from the polishing station to the grinding station (movement from right to left is shown in FIG. 1) in the X direction, laser machining and grinding machining are mainly used to achieve high-efficient and high-precision planarization machining of the surface of the diamond wafer sheet, comprising that: high-power laser quickly removes materials for improving the surface precision of diamond wafer sheet to achieve high-efficient planarization machining of the surface laser machining area, and then molten chips, impact pits, and graphite layers etc. left in the laser machining area are removed by being grinded to achieve further high-precision planarization machining, and simultaneously, the grinding fluid quickly flows into the area where the laser machining is completed, and takes away heat generated by the laser machining on the diamond wafer sheet, thereby avoiding thermal stress or thermal deformation caused by heat accumulation; and

when the diamond wafer sheet moves from the grinding station to the polishing station (movement from left to right is shown in FIG. 1) in the X direction, the laser power is reduced, and polishing machining of the surface of diamond wafer sheet is realized by polishing with the aid of low-power laser thermal induction; specifically, low-power laser irradiating on the surface of diamond wafer sheet is not enough to destroy internal crystal structure of the diamond, but absorbed laser energy heats the surface of the diamond wafer sheet in a form of heat conduction, thereby making a diamond difficult-to-grind material softened, and then the disc-shaped diamond grinding wheel 5D polishes the diamond wafer sheet, removes an extremely thin material layer on the surface, reduces surface roughness of diamond wafer sheet, thereby quickly completing the polishing machining of the diamond wafer sheet;
4.4: performing real-time detection on surface precision: starting the line laser displacement sensor 6B to collect surface morphology data when the diamond wafer sheet makes a straight reciprocation in the X direction, and performing real-time data processing in the central controller to obtain a current machining surface precision of diamond wafer sheet, wherein

the laser displacement sensor detects the surface precision result of the diamond wafer sheet in real time, in an early stage of machining, the surface precision of the diamond wafer sheet is poor, so the laser machining continuously uses high power to mainly focus on high-efficiency planarization machining for rapid material removal; in a mid-stage of machining, the surface precision of the diamond wafer sheet reaches a certain requirement, then the laser machining adopts the above-mentioned mode of reciprocating switching between high and low power in the X direction to achieve high-efficiency and high-precision planarization machining, and avoid deterioration of the surface roughness of the diamond wafer sheet; and in a later stage of machining, the surface precision of the diamond wafer sheet has reached a standard, the laser machining continuously uses low power to mainly focus on the polishing machining of extremely thin material removal, and stops machining until when the entire surface roughness of the diamond wafer sheet also reaches the standard; and
4.5: performing rotary machining on diamond wafer sheet, wherein a stroke range of the X-direction straight reciprocation of the diamond wafer sheet is that one edge (the left side shown in FIG. 1) of the diamond wafer sheet is polishing-machined in place by the disc-shaped diamond grinding wheel 5D, and the other edge (the right side shown in FIG. 1) of the diamond wafer sheet is grinding-machined in place by the grinding cast iron disc; after completing one X-direction reciprocation, the diamond wafer sheet self-rotates by a certain angle ω (5°≤ω≤90°), starting to execute the next X-direction reciprocating machining cycle; and

high-energy laser spot Y-direction straight reciprocating irradiation is performed on the surface of diamond wafer sheet for the laser machining, the grinding disc and the disc-shaped diamond grinding wheel 5D self-rotate to perform the grinding and polishing machining on the diamond surface, the X-direction straight reciprocation of the diamond wafer sheet realizes the combined machining of entire surface of the diamond wafer sheet, and the self-rotation of the diamond wafer sheet makes the surface machining of the diamond wafer sheet more uniform; and

step 5: performing machining result detection, wherein

when the surface precision result of the diamond wafer sheet detected by the line laser displacement sensor 6B in real time reaches the standard, and the entire surface is polished evenly and has no visible defects, the laser emitting apparatus 3A stops emitting laser light, the line laser displacement sensor 6B stops collecting data, and the first pressing cylinder 4B drives the grinding cast iron disc to rise and separate from the diamond wafer sheet, the first swing frame 4A drives the grinding component 4 away from the machining area, the second pressing cylinder 5B drives the disc-shaped diamond grinding wheel 5D to rise and separate from the diamond wafer sheet, the second swing frame 5A drives the polishing component 5 away from the machining area, and then the machining motion platform brings the diamond wafer sheet to a position where it is convenient to take the sheet before stopping the movement; and

a vacuum adsorption apparatus is turned off, the diamond wafer sheet is removed, and a white light interference three-dimensional profiler, a thickness gauge, etc. are used to detect curvature, warpage, surface roughness, total thickness deviation, average thickness and other items of the diamond wafer sheet after machining, so as to verify whether the planarization machining and polishing machining results meet index requirements, if the index requirements are met, the machining ends, and if the index requirements are not met, it returns to corresponding steps for remachining.

The present disclosure uses laser to efficiently remove diamond materials, greatly reduces the removal margin of mechanical grinding, thereby reducing grinding pressure, avoiding deformation or damage of wafers caused by excessive mechanical stress generated in the grinding process, and taking into account the high efficiency and high precision of planarization machining; further, the present disclosure uses laser thermal induction to assist in polishing the diamond wafer sheet, which reduces the difficulty of polishing diamond, reduces the polishing pressure, avoids micro-cracks or even breakage on the wafer surface during the polishing process, and realizes the high efficiency and high quality of the polishing machining. Further, the present disclosure breaks through size limitation of CVD diamond wafer sheet, can machine CVD diamond wafer sheets with different sizes and types, has strong applicability, can greatly reduce the machining cost of diamond wafer sheets, and facilitates the popularization and application of diamond wafer sheet products.

In the description of the present disclosure, it should be noted that orientation and positional relations indicated by terms such as “center”, “lateral”, “longitudinal”, “length”, “width”, “thickness”, “upper”, “lower”, “front”, “back”, “left”, “right”, “vertical”, “horizontal”, “top”, “bottom”, “inner”, “outer”, “clockwise”, and “counterclockwise” are based on orientation or positional relations as shown in the drawings, merely for facilitating the description of the present disclosure and simplifying the description, rather than indicating or implying that related devices or elements have to be in the specific orientation, or configured or operated in a specific orientation, they should not be construed as limiting the specific protection scope of the present disclosure.

It should be noted that the terms “comprising” and “having” and any modifications thereof in the specification and claims of the present disclosure are intended to cover non-exclusive inclusion. For example, a process, method, system, product or device comprising a series of steps or units is not necessarily limited to those steps or units expressly listed, but may include other steps or units not expressly listed or inherent to this process, method, product or device, or may include other steps or units not explicitly disclosed herein but understood by one of ordinary skill in the art to perform the functions or achieve the characteristics that are expressly disclosed herein.

Note that the above are only the preferred embodiments and the technical principle of application in the present disclosure. Those skilled in the art will understand that the present disclosure is not limited to the specific embodiments described herein, and various obvious changes, readjustments and substitutions can be made by those skilled in the art without departing from the protection scope of the present disclosure. Therefore, although the present disclosure is described in more detail through the above embodiments, the present disclosure is not limited to the specific embodiments described herein, and can also include other effective embodiments without departing from the concept of the present disclosure, and the scope of the present disclosure is determined by the scope of the appended claims.

What is claimed is:

1. A high-efficiency and high-precision combined machining equipment for a diamond wafer sheet, comprising a machine frame, wherein the machine frame comprises a base and a support frame, and the support frame is fixedly provided on the base, and a machining motion platform component configured to fix a workpiece to be machined and capable of moving in mutual perpendicular directions of a horizontal plane and rotating in the horizontal plane is installed on the base, a laser machining component, a grinding component, a polishing component and a detection component are installed on the support frame, wherein the laser machining component comprises a laser emitting apparatus, a YZ-direction biaxial motion sliding table, and a laser rotating shaft, the YZ-direction biaxial motion sliding table is installed on the support frame, and the laser emitting apparatus is fixed on the YZ-direction biaxial motion sliding table through the laser rotating shaft, through a movement of the YZ-direction biaxial motion sliding table and the laser rotating shaft, a high-energy laser beam can be focused on a surface of a diamond wafer sheet to be machined, and an incident angle of the high-energy laser beam and a horizontal Y-direction straight reciprocating irradiation of a laser spot are adjusted;
the grinding component comprises a first swing frame, a first pressing cylinder, a grinding motorized spindle, a grinding disc, a grinding liquid filtering and circulating apparatus and a flexible scraper blade, wherein one end of the first swing frame is installed on the support frame and can make arc swing around its own rotating shaft in the horizontal plane; the first pressing cylinder is fixed on the first swing frame, the first pressing cylinder is provided vertically downward, a movable end of the first pressing cylinder is connected to the grinding motorized spindle, and a rotating shaft of the grinding motorized spindle is connected to the horizontally arranged grinding disc, and the grinding disc is driven by the first swing frame to move to a grinding station above the machining motion platform component; and the flexible scraper blade is fixed on a shell of the grinding motorized spindle, and is close tightly to an outside of the grinding disc;
the polishing component comprises a second swing frame, a second pressing cylinder, a polishing motorized spindle, and a disc-shaped diamond grinding wheel, wherein one end of the second swing frame is installed on the support frame, and can make arc swing around its own rotating shaft in the horizontal plane; the second pressing cylinder is fixed on the second swing frame, the second pressing cylinder is provided vertically downward, a movable end of the second pressing cylinder is connected to the polishing motorized spindle, and a rotating shaft of the polishing motorized spindle is connected to the horizontally arranged disc-shaped diamond grinding wheel, the diamond grinding wheel is driven by the second swing frame to move to a polishing station above the machining motion platform component;
the detection component is provided directly above the machining motion platform component, which comprises a Z-direction vertical displacement sliding table and a line laser displacement sensor, wherein the line laser displacement sensor is fixed vertically downward on the Z-direction vertical displacement sliding table, and configured to scan a surface of diamond to be machined, so as to obtain a morphology height displacement data, wherein
when the grinding component, polishing component, and detection component are all located at a machining station, the grinding disc, the line laser displacement sensor, and the disc-shaped diamond grinding wheel are in sequence arranged in a straight line from the grinding station to the polishing station, and the straight line is parallel to a X direction and perpendicularly intersects with a rotation axis of a diamond wafer sheet; the flexible scraper blade is provided between the grinding station and the polishing station; and an irradiation area of the laser machining component is located between the grinding station and polishing station; and
an output end of the line laser displacement sensor is connected to an input end of a central controller, and an output end of the central controller is respectively connected to control input ends of the laser emitting apparatus, the machining motion platform component, the laser machining component, the grinding component, the polishing component, and the detection component.

2. The high-efficiency and high-precision combined machining equipment for a diamond wafer sheet according to claim 1, wherein the machining motion platform component comprises an XY-direction two-dimensional horizontal motion platform in a horizontal plane, a rotating carrier platform, a transition carrier plate and a vacuum adsorption apparatus, wherein the XY-direction two-dimensional horizontal motion platform, the rotating carrier platform, and the transition carrier plate are in sequence provided from bottom to top, and an upper end surface of the rotating carrier platform is provided with gas holes and gas passages, and the gas holes and the gas passages are connected to a suction port of the vacuum adsorption apparatus through a rotating joint; the transition carrier plate and the rotating carrier platform are provided coaxially; a central position of an upper end surface of the transition carrier plate is provided with a circular groove configured for placement of the workpiece to be machined, and several through holes are evenly distributed in the circular groove, the through holes communicate with the gas passages on the upper end surface of the rotating carrier platform; a diameter of the circular groove of the transition carrier plate is the same as a diameter of the diamond wafer sheet to be machined, and a depth of the circular groove is smaller than a thickness of the diamond wafer sheet to be machined.

3. The high-efficiency and high-precision combined machining equipment for a diamond wafer sheet according to claim 1, wherein an edge position of a lower disk surface of the grinding disc is provided with a circular ring protrusion, and a grid-shaped diversion trench is provided on the circular ring protrusion, and multiple diversion holes are evenly distributed in the diversion trench, a liquid flow channel is provided inside the grinding disc, and the liquid flow channel is communicated with all the diversion holes, an end of the liquid flow channel is led to a total liquid inlet in a center of the grinding disc and communicated with a liquid outlet of the grinding liquid filtering and circulating apparatus through a rotating joint and a hose.

4. The high-efficiency and high-precision combined machining equipment for a diamond wafer sheet according to claim 1, further comprising a metal housing, wherein the metal housing is covered on the base for wrapping and protection.

5. A high-efficiency and high-precision combined machining method for a diamond wafer sheet, comprising following steps of:
placing a diamond wafer sheet to be machined at a machining station, and obtaining a highest point position information of the diamond wafer sheet and a surface precision result of a surface flatness;
setting a laser incident angle, a laser machining power, a straight reciprocating speed of a laser in a Y-direction, a straight reciprocating speed of the diamond wafer sheet in an X-direction perpendicular to the Y-direction, a rotational speed of a grinding disc, a rotational speed of a diamond grinding wheel, and gas supply pressures of a first pressing cylinder and a second pressing cylinder;
the diamond wafer sheet making a reciprocating motion in the X direction at a first set speed, a laser emitting apparatus making a straight reciprocating motion in the Y-direction at a second set speed, and a high-energy laser beam making a straight reciprocating irradiation on the diamond wafer sheet in the Y-direction at a set incident angle to perform laser planarization machining;
a grinding disc and a diamond grinding wheel rotating, under an action of the laser, at a constant speed according to their respective set rotational speeds, and the first pressing cylinder and the second pressing cylinder pressing downwards for grinding and polishing, so as to achieve further high-precision grinding planarization and finishing polishing machining, at least in part concurrently, turning on, during a machining process, a grinding liquid filtering and circulating apparatus, wherein in the machining process, a surface precision of the diamond wafer sheet is detected in real time, and a central controller performs data processing in real time to obtain a current machined surface precision of the diamond wafer sheet; and
the diamond wafer sheet self-rotating, after the diamond wafer sheet completes one X-direction straight reciprocating stroke range, by a certain angle, and starting to execute a next X-direction reciprocating machining cycle until machining requirements are reached before ending.

6. The high-efficiency and high-precision combined machining method for a diamond wafer sheet according to claim 5, wherein the method further comprises:
performing in-situ detection on the surface precision of the diamond wafer sheet, further comprising:
fixing the diamond wafer sheet, comprising placing the diamond wafer sheet in a central circular groove of a transition carrier plate, and turning on a vacuum adsorption to fix the diamond wafer sheet and the transition carrier plate;
adjusting a detection position, comprising turning on a line laser displacement sensor to emit a measurement laser beam for irradiating on a surface of the diamond wafer sheet, a Z-direction vertical displacement sliding table driving the line laser displacement sensor to move up or down, and adjusting a height position of the line laser displacement sensor distancing from the diamond wafer sheet, so that the line laser displacement sensor detects a middle value of a displacement value located in a measuring range thereof; moving a XY-direction two-dimensional horizontal motion platform to adjust a front-and-rear Y-direction position of the diamond wafer sheet, so that a linear laser beam emitted by the line laser displacement sensor covers a diameter line of the diamond wafer sheet; driving the XY-direction two-dimensional horizontal motion platform and moving the diamond wafer sheet in a left-and-right X direction to one side of the line laser displacement sensor; and
performing the in-situ detection and data processing, comprising driving the XY-direction two-dimensional horizontal motion platform and moving the diamond wafer sheet at a constant speed in the left-and-right X-direction to a second side of the line laser displacement sensor, wherein during the movement, the line laser displacement sensor continuously emits a linear measurement laser beam to scan a surface of the diamond wafer sheet, so as to collect a morphology displacement data of the surface of the diamond wafer sheet; and obtaining, according to data processing steps comprising point cloud coordinate transformation, effective point screening, empty point interpolation, three-dimensional morphology construction, and index value calculation performed in sequence on collected data, the highest point position information of the diamond wafer sheet and the surface precision result of the surface flatness;
initializing a machining condition, further comprising:
adding a protective coating, comprising, where an upper surface of the diamond wafer sheet is higher than a surface of the transition carrier plate, coating a thickness of protective coating along a circumferential side surface of the diamond wafer sheet, so that a thickness of the protective coating is flush with the upper surface of the diamond wafer sheet, wherein after being cured, the protective coating reduces absorption rate of laser energy on the circumferential side surface of the diamond wafer sheet, and mechanically supports a circumferential edge of the diamond wafer sheet to mitigate deformation of the edge of the diamond wafer sheet in response to the high-efficiency and high-precision combined machining method;
adjusting high-energy laser beam focusing, comprising using parameters comprising an incident angle of a high-energy laser beam, a laser focal distance, a highest point position coordinate and a height of the diamond wafer sheet to calculate a coordinate position of a light outlet of the laser emitting apparatus in the front-and-rear Y-direction and an up-and-down Z-direction according to a trigonometric function relationship, and then, enabling, through rotation of a laser rotating shaft, movement of a YZ-direction biaxial motion sliding table, and movement of the XY-direction two-dimensional horizontal motion platform, the high-energy laser beam emitted by the laser emitting apparatus to be irradiated and focused on a highest point position of a surface of the diamond wafer sheet at a set incident angle; and
entering machining station, comprising moving, through rotation of a first swing frame and a second swing frame, a grinding disc and a disc-shaped diamond grinding wheel to above the diamond wafer sheet, respectively, so that the grinding disc, the line laser displacement sensor, and the disc-shaped diamond grinding wheel are in sequence arranged in a straight line from left to right, wherein the straight line is parallel to the X direction and perpendicularly intersects with a rotation axis of the diamond wafer sheet; and the laser emitting apparatus is located directly in front of the line laser displacement sensor;
setting a machining parameter, comprising
setting laser incident angles, comprising carrying out a proofing test with different laser incident angles on a diamond test piece, recording, under a condition of highest laser power, a difference value of ablation depth between positive focus and 0.02 mm defocus, and selecting as the machining parameter a laser incident angle θ when the difference value is the largest;
setting laser machining powers, comprising carrying out a proofing test with different laser powers on the diamond test piece, selecting a laser power P₁ with a largest ablation depth and no micro-cracks in an ablation area as a first setting power for a laser high-efficiency planarization machining, and selecting a laser power P₂ when an ablation depth is 0 and an ablation area is not blackened and darkened as a second setting power for a laser low-power thermally induced machining;
setting reciprocating motion speeds, comprising carrying out a proofing test under a condition of the laser power P₁ on the diamond test piece, measuring a length j, a width k and an area of an ablation pit, and then setting, according to a center repetition frequency Q of a high-power pulsed laser, an ideal spot overlap ratio E, shape size of the ablation pit, and a Y-direction reciprocating motion stroke H, a straight reciprocating speed V_{y} of the laser in the Y-direction and a straight reciprocating speed Vₓ of the diamond wafer sheet in the X-direction, consistent with a relational expression:
V_{y}=j·ϵ·Q
Vₓk·ϵ·V_{y}/H
wherein unit of Vₓ is mm/s, unit of V_{y} is mm/s, unit of j is mm, unit of k is mm, unit of Q is Hz, unit of H is mm, and ratio unit of ϵ is 1;
setting rotational speeds, comprising setting, according to a circular ring protrusion width w₁ of the grinding disc, a working layer width w₂ of the disc-shaped diamond grinding wheel, an ideal repeated grinding coefficient τ₁ of grinding, an ideal repeated grinding coefficient τ₂ of polishing, and the straight reciprocating speed Vₓ of the diamond wafer sheet in the X-direction, a rotational speed n₁ of the grinding disc and a rotational speed n₂ of the disc-shaped diamond grinding wheel, consistent with a second relational expression:
n₁Vₓ/τ₁·w₁
n₂Vₓ/τ₂·w₂
wherein unit of n₁ is r/s, unit of n₂ is r/s, unit of w₁ is mm, unit of w₂ is mm, and ratio unit of τ₁ and τ₂ is 1; and
setting gas pressures, comprising setting a gas supply pressure R₁ of the first pressing cylinder according to a mass m₁ of a grinding component, an ideal grinding pressure F₁ and a cylinder diameter φ₁ of the first pressing cylinder, and setting a gas supply pressure R₂ of the second pressing cylinder according to a mass m₂ of a polishing component, an ideal polishing pressure F₂ and a cylinder diameter φ₂ of the second pressing cylinder, consistent with a third relational expression:
R₁=4(F₁−m₁g)/π·φ₁²
R₂=4(F₂−m₂g)/π·φ₂²
wherein unit of R₁ and R₂ is Pa, unit of F₁ and F₂ is N, unit of m₁ and m₂ is kg, unit of φ₁ and φ₂ is m, and g is a constant of gravitational acceleration, and π is a constant of pi; and
starting combined machining, comprising
the diamond wafer sheet making reciprocating motion in the X-direction, comprising starting the XY-direction two-dimensional horizontal motion platform to drive the diamond wafer sheet to make a straight reciprocating motion in the X-direction according to the set speed Vₓ,
performing reciprocating laser machining in the Y-direction, comprising starting the YZ-direction biaxial motion sliding table to drive the laser emitting apparatus to make a straight reciprocating motion in the Y-direction according to the set speed V_{y}, so that the high-energy laser beam performs a straight reciprocating irradiation on the diamond wafer sheet in the Y direction at a set incident angle θ, which cooperates with X-direction reciprocation of the diamond wafer sheet to achieve a laser planarization machining of high point more removal material and low point less removal material on an entire surface of the diamond wafer sheet;
performing combined grinding and polishing machining under an action of the laser, comprising starting a grinding motorized spindle and a polishing motorized spindle, so that the grinding disc and the disc-shaped diamond grinding wheel rotate at a constant speed according to their respective set rotational speeds n₁ and n₂, and the circular ring protrusion of the grinding disc and a working layer of the disc-shaped diamond grinding wheel contact the surface of the diamond wafer sheet through pressing actions and pressures of the first pressing cylinder and the second pressing cylinder, so as to achieve further high-precision grinding planarization and finishing polishing machining; and at least in part concurrently, turning on the grinding fluid filtering and circulating apparatus, so that a diamond grinding fluid is injected into a grinding area on the surface of the diamond wafer sheet from a liquid flow channel, diversion holes and diversion trench of the grinding disc, and a flexible scraper blade is in firm contact with the surface of the diamond wafer sheet to prevent the grinding fluid from flowing into a laser machining area and a polishing area;
performing real-time detection on surface precision, comprising starting the line laser displacement sensor to collect surface morphology data when the diamond wafer sheet makes a straight reciprocation in the X direction, and performing real-time data processing in the central controller to obtain a current machining surface precision of the diamond wafer sheet; and
performing rotary machining on the diamond wafer sheet, wherein a stroke range of the X-direction straight reciprocation of the diamond wafer sheet is that one edge of the diamond wafer sheet is polishing-machined in place by the disc-shaped diamond grinding wheel, and the other edge of the diamond wafer sheet is grinding-machined in place by the grinding disc; after completing one X-direction reciprocation, the diamond wafer sheet self-rotates by a certain angle ω, starting to execute the next X-direction reciprocating machining cycle.

7. The high-efficiency and high-precision combined machining method for a diamond wafer sheet according to claim 6, wherein when the diamond wafer sheet moves from the polishing station to the grinding station in the X direction, laser machining and grinding machining achieve high-efficient and high-precision planarization machining for the surface of the diamond wafer sheet, comprising that: the high-energy laser beam emitted by the laser emitting apparatus quickly removes materials for improving the surface precision of the diamond wafer sheet to achieve high-efficient planarization machining of a surface laser machining area, and then molten chips, impact pits, and graphite layers left in the laser machining area are removed by being grinded to achieve further high-precision planarization machining, and at least in part concurrently, the grinding fluid quickly flows into an area where a laser machining is completed, and takes away heat generated by the laser machining on the diamond wafer sheet, thereby avoiding thermal stress or thermal deformation caused by heat accumulation.

8. The high-efficiency and high-precision combined machining method for a diamond wafer sheet according to claim 7, wherein when the diamond wafer sheet moves from the grinding station to the polishing station in the X direction, a laser power of the high-energy laser beam is reduced, and polishing machining of the surface of the diamond wafer sheet is realized by polishing with an aid of low-power laser thermal induction, wherein low-power laser irradiating on the surface of the diamond wafer sheet is not enough to destroy internal crystal structure of diamond, but absorbed laser energy heats the surface of the diamond wafer sheet in a form of heat conduction, thereby making a diamond difficult-to-grind material softened, and then the disc-shaped diamond grinding wheel polishes the diamond wafer sheet, removes an extremely thin material layer on the surface, reduces surface roughness of the diamond wafer sheet, thereby quickly completing the polishing machining for the diamond wafer sheet.

9. The high-efficiency and high-precision combined machining method for a diamond wafer sheet according to claim 8, wherein during the machining process, the laser displacement sensor detects the surface precision result of the diamond wafer sheet in real time, in an early stage of machining, the surface precision of the diamond wafer sheet is poor, so the laser machining continuously uses high power to mainly focus on high-efficiency planarization machining for rapid material removal; in a mid-stage of machining, the surface precision of the diamond wafer sheet reaches a certain requirement, then the laser machining adopts the mode of reciprocating switching between high and low power in the X direction to achieve high-efficiency and high-precision planarization machining, and avoid deterioration of the surface roughness of the diamond wafer sheet; and in a later stage of machining, the surface precision of the diamond wafer sheet has reached a standard, the laser machining continuously uses low power to mainly focus on the polishing machining of extremely thin material removal, and stops machining until a surface roughness of the diamond wafer sheet further reaches a predetermined surface roughness measurement.

10. The high-efficiency and high-precision combined machining method for a diamond wafer sheet according to claim 9, further comprising performing machining result detection, wherein
when the surface precision result of the diamond wafer sheet detected by the line laser displacement sensor in real time reaches the predetermined surface roughness measurement, the laser emitting apparatus stops emitting laser light, the line laser displacement sensor stops collecting data, and the first pressing cylinder drives the grinding disc to rise and separate from the diamond wafer sheet, the first swing frame drives the grinding component away from the machining area, the second pressing cylinder drives the disc-shaped diamond grinding wheel to rise and separate from the diamond wafer sheet, the second swing frame drives the polishing component away from the machining area, and then the machining motion platform brings the diamond wafer sheet to a removal position and stops movement; and
a vacuum adsorption apparatus is turned off, the diamond wafer sheet is removed, and a white light interference three-dimensional profiler, and a thickness gauge are used to detect curvature, warpage, surface roughness, total thickness deviation and average thickness of the diamond wafer sheet after machining, so as to verify whether planarization machining and polishing machining results meet index requirements, wherein the machining ends in response to the index requirements being met, and re-machining begins in response to the index requirements not being met.

11. The high-efficiency and high-precision combined machining equipment for a diamond wafer sheet according to claim 2, further comprising a metal housing, wherein the metal housing is covered on the base for wrapping and protection.

12. The high-efficiency and high-precision combined machining equipment for a diamond wafer sheet according to claim 3, further comprising a metal housing, wherein the metal housing is covered on the base for wrapping and protection.
